(19) United States
(12) Patent Application Publication
(10) Pub. No.: US 2001/0006039 A1
(43) Pub. Date: Jul. 5, 2001

(54) Method for manufacturing an epitaxial silicon wafer

(76) Inventors: Won-Ju Cho, Cheongju (KR); Hyun-Suk Shim, Cheongju (KR); Young-Kuk Cha, Cheongju (KR)

Correspondence Address: BIRCH, STEWART, KOLASCH & BIRCH, LLP, P.O. Box 747, Falls Church, VA, 22040-0747, US

(21) Appl. No.: 09/749,665

(22) Filed: Dec. 28, 2000

(30) Foreign Application Priority Data
Jan. 5, 2000 (KR) 283/2000

(51) Int. Cl. C30B 15/00

(52) U.S. Cl. 117/13; 117/84

(57) ABSTRACT

In the method of manufacturing an epitaxial silicon wafer, a silicon wafer substrate is hydrogen-annealed to remove impurities and defects. Then, an impurity buried layer is formed in an upper surface of the silicon wafer substrate. The impurity buried layer increases the number of contaminant attractors in the upper surface of the silicon wafer substrate. As a result, during the subsequent formation of a silicon epitaxial layer, the contaminant attractors attract contaminants away from the silicon epitaxial layer.

### BACKGROUND OF THE INVENTION

1. Field of the Invention

The present invention relates to a method for manufacturing a silicon wafer for use in fabricating a semiconductor device and, in particular, to a method for manufacturing an epitaxial silicon wafer having a reduced amount of impurities existing on a silicon epitaxial layer.

2. Description of the Prior Art

Single crystal silicon for use as a wafer material for a semiconductor substrate is usually fabricated by the Czochralski method (hereinafter, the CZ method). The CZ method is a method in which a seed crystal is soaked in fused silicon positioned in a quartz crucible, and then a single silicon ingot is grown by pulling the seed crystal while rotating the crucible and the seed crystal. After growing the single crystal silicon ingot, slicing, lapping and polishing are performed to thereby fabricate a single crystal silicon wafer.

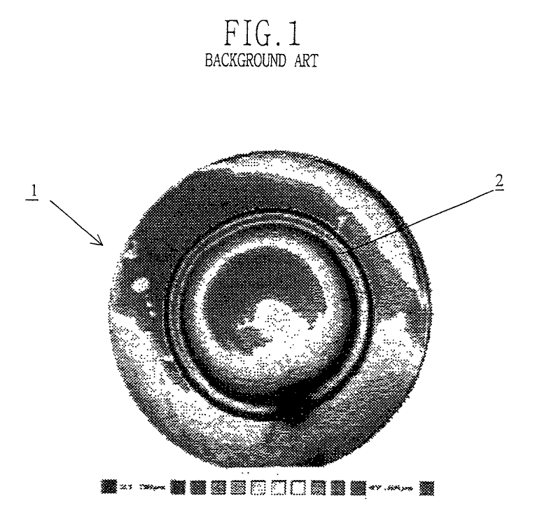

FIG. 1 illustrates a horizontal picture of a single crystal silicon wafer 1 fabricated by the conventional CZ method. As illustrated therein, typical surface defects found in the conventional single crystal wafer 1 include an OSF ring (oxidation-induced stacking faults ring) 2. The OSF ring 2 is generated in annealing a silicon wafer, and moves toward the outer parts of the silicon wafer 1 as the pulling speed of a seed crystal is increased. In a silicon wafer grown at certain pulling speeds, the OSF ring does not occur.

The inner part of the OSF ring 2 of the silicon wafer 1 becomes a vacancy-rich region, and the outer part becomes a interstitial silicon atom-rich region. Besides the OSF ring 2, surface defects such as interstitial atoms, vacancies, voids and precipitates are found in the silicon wafer.

As the integration of a device increases, the effect of surface defects existing in a silicon wafer on the reliability of the device increases. Thus, an improved surface layer of a wafer is required so as to improve the reliability of the device, and a method of forming a silicon epitaxial layer on the surface of a silicon wafer substrate fabricated by the CZ method is used so as to satisfy the above requirement. By forming the silicon epitaxial layer on the upper surface of the silicon wafer substrate, the effect of the above-described various surface defects on the reliability of a device can be decreased.

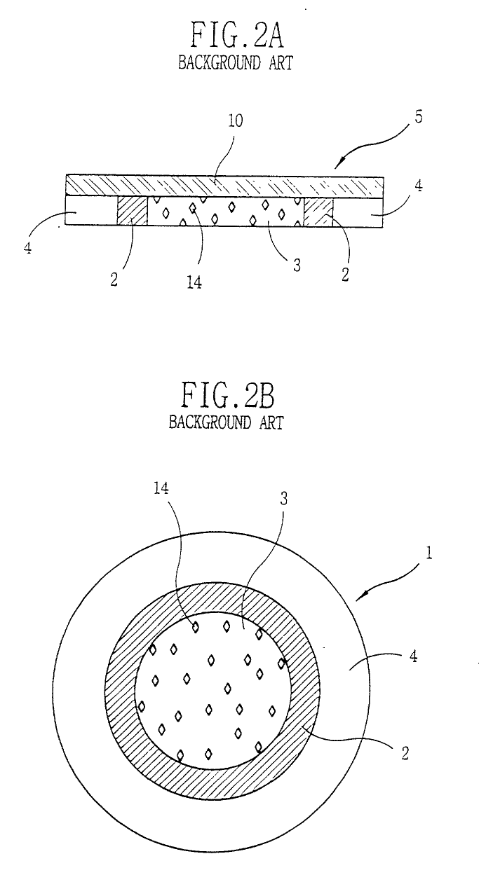

FIG. 2A illustrates a vertical cross-sectional view of the conventional epitaxial silicon wafer 5, and FIG. 2B illustrates a plane view of a silicon wafer substrate 1 for use as a substrate of the epitaxial silicon wafer.

As illustrated therein, the OSF ring 2 separates the wafer substrate 1 into a vacancy-rich region 3, and an interstitial silicon atom-rich region 4. A plurality of voids 14 exist in the vacancy-rich region 3. A silicon epitaxial layer 10 is formed on the upper surface of the silicon wafer substrate 1.

However, the conventional epitaxial silicon wafer 5 has problems because it deposits and forms a silicon epitaxial layer 10 on the upper surface of a polished silicon wafer substrate 1, without considering the growth conditions and crystal characteristics of the silicon wafer substrate 1.

Firstly, since the conventional epitaxial silicon wafer 5 is manufactured for the purpose of removing surface defects, the silicon wafer substrate I is simply used as a substrate material for forming a silicon epitaxial layer 10, and does not play the role of removing metal contaminants in a silicon epitaxial layer 10 generated due to external factors in the process of forming a silicon epitaxial layer. Unfortunately, in practice, metal contaminants are the most important problem faced in forming a silicon epitaxial layer. The metal contaminants result from the equipment used in forming a silicon epitaxial layer, and originate from, for example, a gas line to which source gas used in the formation process is supplied. These metal contaminants may cause a fatal flaw in a device fabricated on the epitaxial silicon wafer, thereby resulting in a decreased yield.

When a silicon wafer is annealed during the following process, an OSF ring is formed and, thereby, the shape of lattice defects in the same silicon wafer substrate change. Thus, the effect of removing metal contaminants on the silicon wafer substrate varies according to the border of the OSF ring, and the characteristics of the device are degraded in the OSF ring region.

In addition, since the silicon wafer substrate used in fabricating the conventional epitaxial silicon wafer is fabricated by the CZ method of low pulling speed, the time taken for a silicon wafer substrate to be fabricated increases; thereby increasing the unit price of the epitaxial silicon wafer.

Furthermore, in the conventional epitaxial silicon wafer, because the doping concentration of the silicon wafer substrate is high, and because the yield is low, the unit price of the epitaxial silicon wafer increases.

### SUMMARY OF THE INVENTION

In the method of manufacturing an epitaxial silicon wafer according to the present invention, a silicon ingot is grown, and from the ingot, a silicon wafer substrate is obtained. An impurity buried layer is formed in an upper surface of the silicon wafer substrate. Preferably, nitrogen is used to form the impurity buried layer. The impurity buried layer causes the creation of an increased number of oxygen deposits in the upper surface of the silicon wafer substrate. As a result, during the subsequent formation of a silicon epitaxial layer, the oxygen deposits act as contaminant attractors, and attract contaminants away from the silicon epitaxial layer. This has the advantage of increasing the reliability, and therefore, yield of the epitaxial silicon wafer.

Additionally, prior to forming the impurity buried layer, the silicon wafer substrate is hydrogen-annealed to remove impurities, a native oxide film, and other defects.

Furthermore, the silicon ingot is grown according to the CZ method at a pulling speed sufficient to prevent the formation of an OSF ring and improve the speed of formation such as to lower a unit price.

### BRIEF DESCRIPTION OF THE INVENTION

The present invention will become more fully understood from the detailed description given hereinbelow and the accompanying drawings which are given by way of illustration only, and thus are not limitative of the present invention, and wherein:

FIG. 1 is a plane picture of a conventional silicon wafer;

FIG. 2A is a vertical cross-sectional view of a conventional epitaxial silicon wafer;

FIG. 2B is a plane view of a conventional silicon wafer substrate;

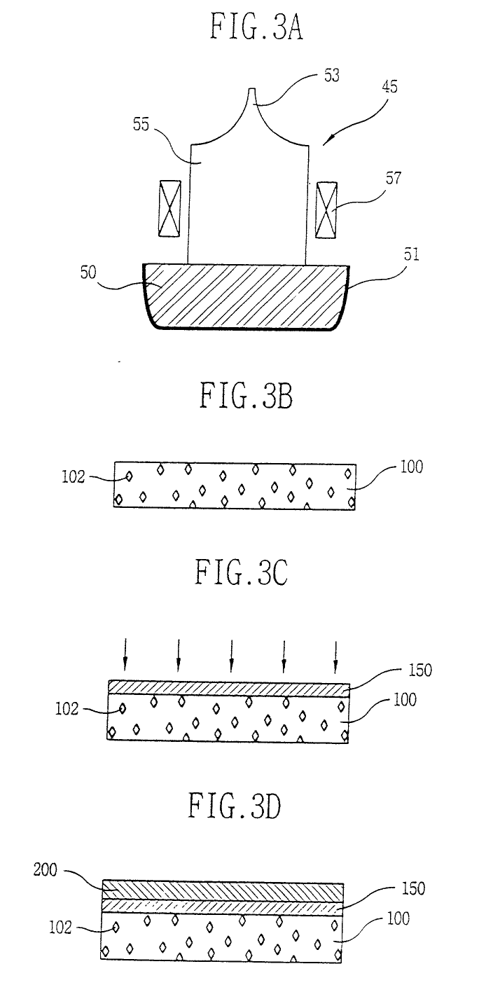

FIGS. 3A-3D are sequential process charts showing a method for manufacturing an epitaxial silicon wafer according to a first embodiment of the present invention;

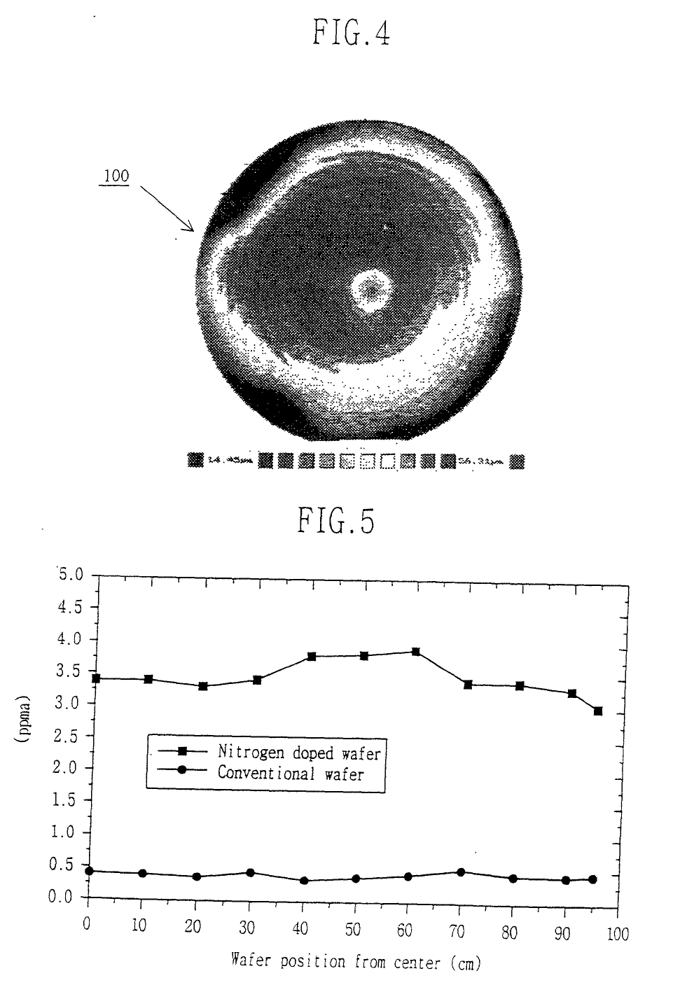

FIG. 4 is a plane picture of a silicon wafer substrate according to the present invention;

FIG. 5 is a graph illustrating the deposition amount of oxygen in a silicon wafer substrate in which an impurity buried layer is formed and the deposition amount of oxygen in a silicon wafer substrate in which an impurity buried layer is not formed;

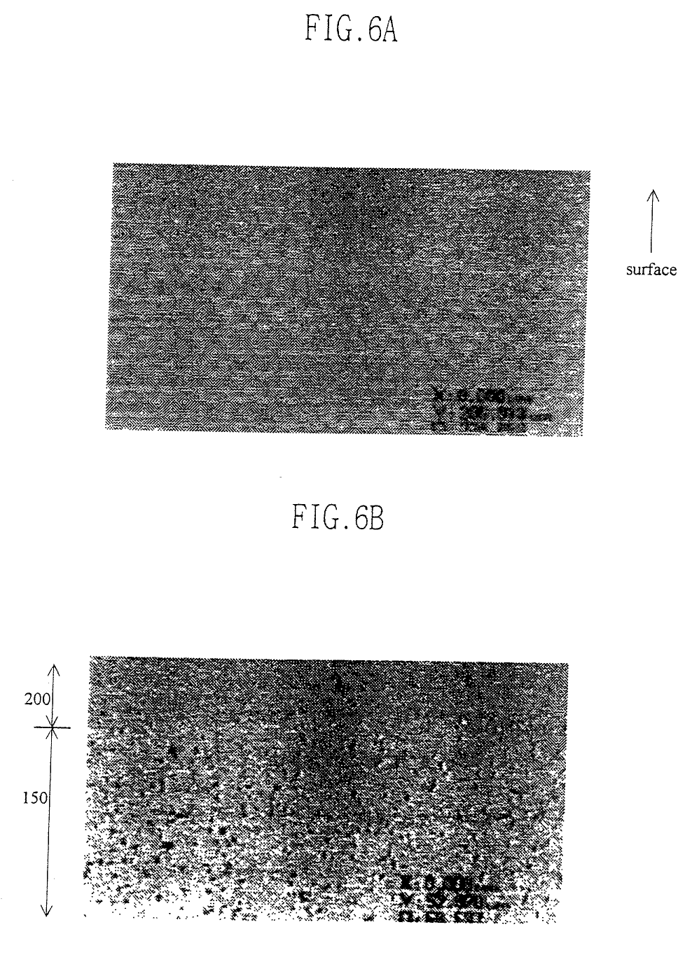

FIG. 6A is a photomicrograph showing a vertical cross-section of an epitaxial wafer in the case of forming a silicon epitaxial layer when an impurity buried layer is not formed on the upper surface of a silicon wafer substrate;

FIG. 6B is a photomicrograph showing a vertical cross-section of an epitaxial wafer in the case of forming a silicon epitaxial layer after forming a impurity buried layer on the upper surface of a silicon wafer substrate.

### DETAILED DESCRIPTION OF THE PREFERRED EMBODIMENTS

A method for manufacturing an epitaxial silicon wafer according to a preferred embodiment of the present invention will be described in detail with reference to the accompanying drawings.

FIGS. 3A-3D illustrate a method for manufacturing an epitaxial silicon wafer according to one embodiment of the present invention.

Firstly, FIG. 3A illustrates a method for growing a single silicon ingot by the CZ method. After soaking a seed crystal 53 in fused silicon 50 positioned within a quartz crucible 51 of a crystal growth furnace 45, a single crystal silicon ingot 55 is grown by rotating the crucible 51 and the seed crystal while pulling the seed crystal. At this time, the pulling speed is controlled, so that an OSF ring is not formed on a silicon wafer substrate. In the present embodiment, the seed crystal is pulled at a speed of more than 0.4 mm/sec. In addition, in order to prevent vacancy defects formed in the ingot 55 from clustering, the growth furnace 45 used in the present embodiment has a hot zone of forced cooling type using a forced cooling unit 57. In the present embodiment, the ratio(V/G) of pulling speed(V) to temperature gradient(G) is more than 0.2 mm²/° C. min. The impurities, p-type or n-type, to dope the silicon are added to the fused silicon 50 positioned within the quartz crucible 51, and then the single crystal silicon ingot 55 is grown to thereby be doped with p-type or n-type impurities. In the present embodiment, the doping concentration of the ingot 55 ranges from 1×10¹⁰ to 1× 10¹⁸cm⁻³.

Next, FIG. 3B illustrates a vertical cross-sectional view of a silicon wafer substrate 100. As illustrated therein, the silicon wafer substrate 100 is manufactured by slicing, lapping and polishing the single crystal silicon ingot 55. As illustrated in FIG. 4, there is no OSF ring in the silicon wafer substrate 100 manufactured according to the present invention. As a result, a vacancy-rich region is formed all over the silicon wafer substrate 100, and, as illustrated in FIG. 3(b), a plurality of voids 102 exist in the silicon wafer substrate 100. The silicon wafer substrate 100 is washed according to the vapor phase washing method using gas having HF or according to the liquid phase washing method using SC1(Standard Chemical 1), and then it is hydrogen annealed, thereby removing impurities, a native oxide film and COP(Crystal Originated induced particle) defects existing on the surface.

Next, as illustrated in FIG. 3C, impurities are diffused or implanted into the upper surface of the silicon wafer substrate 100 to thereby form an impurity buried layer 150. In the present embodiment, nitrogen(N) at an injection energy of 20 KeV˜3.3 MeV is implanted to thereby form the above impurity buried layer 150 having a nitrogen concentration of 1×10¹⁰˜1×10¹⁶ cm². The nitrogen implanted into the silicon wafer substrate 100 increases the amount of oxygen deposited into the silicon wafer substrate 100. Besides diffusing or implanting impurities such as nitrogen into the silicon wafer substrate 100, it is also possible to dope the impurity buried layer by implantation or diffusion using a gas such as PH₃ or B₂H₆. Preferably, in the present embodiment, the impurity layer is doped with p-type or n-type impurities to a concentration of 1×10¹⁹18 1²² cm² using an epitaxial furnace described above with respect to FIG. 3A.

FIG. 5 is a graph illustrating the change in the amount of oxygen deposited radially from the center of a wafer into which nitrogen is implanted and the change in the amount of oxygen deposited radially from the center of a wafer into which nitrogen is not implanted, after completing a 256 DRAM heat cycle. As illustrated, a large amount of oxygen deposition occurs when nitrogen is implanted as compared to when nitrogen is not implanted.

Lastly, as illustrated in FIG. 3D, a silicon epitaxial layer 200 is formed on the upper surface of the impurity buried layer 150. In the present embodiment, SiHCl₃ or SiH₂CL₂ as source gas and N₂, H₂ and HCl as carrier gas are used to form the silicon epitaxial layer 200 to a thickness of 1 μm˜50 μm at a pressure of 1×10⁻⁴˜1×10⁻⁵ torr and at a temperature of 900˜1200°C. The silicon epitaxial layer 200 is formed using the well-known chemical vapor deposition method and any well-known epitaxial furnace. Optionally, the silicon epitaxial layer 200 can be formed by various other well-known deposition methods including physical vapor deposition. A typical reaction formula by which a silicon epitaxial layer is formed is as follows:

SiHCl₃(gas)+H₂(gas)→Si(solid)+3HCl(gas)

The doping of the above silicon epitaxial layer 200 is performed using PH₃ in case of n-type doping or using B2H₃ in case of p-type doping, by the following reaction formula:

B₂H₆(gas)→2B(solid)+3H₂(gas)

2PH₃(gas)→2P(solid)+3H₂(gas)

The principle for removing contaminants such as metal contaminants in the silicon epitaxial layer 200 using the silicon wafer substrate 100 according to the present invention will now be described.

Most contaminants including metal contaminants have mutual attraction, and, as a result, a contaminant of a little mass moves toward a contaminant of a large mass and these two contaminants react each other. The reaction at that time may be a reaction, for example, which forms oxygen deposits.

FIG. 6A is a photomicrograph showing a vertical cross-section of an epitaxial silicon wafer in the case of forming a silicon epitaxial layer when an impurity buried layer is not formed on the upper surface of a silicon wafer substrate, and FIG. 6B is a photomicrograph of a vertical cross-section of an epitaxial silicon wafer in the case of forming a silicon epitaxial layer after forming an impurity buried layer on the upper surface of a silicon wafer substrate.

In the case of the epitaxial silicon wafer on which an impurity buried layer is formed as illustrated in FIG. 6B as compared to the epitaxial silicon wafer as illustrated in FIG. 6A, it is noted that a plurality of oxygen deposits are formed on the impurity buried layer 150 under the silicon epitaxial layer 200. The oxygen deposits draw or attract contaminants such as metal contaminants away from the silicon epitaxial layer 200, resulting in the removal of the contaminants from the silicon epitaxial layer 200.

The reaction formula by which the oxygen deposits are formed is as follows.

2Si+2Oi+V→SiO₂,

wherein Si designates a silicon atom, Oi designates an interstitial oxygen atom, and V designates a vacancy. As shown in the reaction formula, the vacancy is required in order to form oxygen deposits. The reason is that the formation of oxygen deposits accompanies a cubical expansion and the vacancy alleviates stored energy accompanied by the above mass. Thus, in the case that a vacancy-rich region is formed on the silicon wafer substrate according to the present invention, oxygen deposits are formed better than as compared to the case that the interstitial-rich region is conventionally formed on the silicon wafer substrate.

In the case that an impurity buried layer is not formed, some oxygen deposits are formed in the vacancy-rich region of the silicon wafer substrate to thereby remove the contaminants in the silicon epitaxial layer. However, the efficiency with which contaminants are removed is lower as compared to when an impurity buried layer as in the present invention is formed.

As described above, in the method for manufacturing a semiconductor device and the construction of the same according to the present invention, a single crystal ingot is grown at a relatively fast pulling speed to form a vacancy-rich region on the entire silicon wafer substrate, thereby improving the uniformity of the crystal structure of the silicon wafer substrate and, in particular, improving the ability of the silicon wafer substrate to remove impurities from a silicon epitaxial layer formed thereon.

In addition, in the present invention, the pulling speed of the single crystal silicon ingot is increased to thereby reduce the time taken for each epitaxial silicon wafer to be manufactured and accordingly lower the unit price of the epitaxial silicon wafer.

In addition, in the present invention, since an impurity buried layer is doped, the doping concentration of a single crystal silicon ingot is lowered to thereby lower the unit price of the single crystal silicon ingot growth and improve the yield.

Furthermore, in the present invention, the impurities in the silicon epitaxial layer are removed to thereby increase the reliability of the device manufactured on the epitaxial silicon wafer and accordingly improve the yield of the device.

What is claimed is:

1. A method for manufacturing an epitaxial silicon wafer comprising:
growing a silicon ingot;
manufacturing a silicon wafer substrate by slicing, lapping and polishing the ingot;
hydrogen-annealing the silicon wafer substrate; and
forming a silicon epitaxial layer on the upper surface of the silicon wafer substrate.

2. The method of claim 1, prior to forming a silicon epitaxial layer step, further comprising:
forming an impurity buried layer on the upper surface of the hydrogen-annealed silicon wafer substrate.

3. The method of claim 2, wherein the impurity buried layer is formed by implanting or diffusing nitrogen.

4. The method of claim 3, wherein the concentration of the nitrogen implanted or diffused is 1×10¹⁰˜1×10¹⁶/cm².

5. The method of claim 3, wherein a nitrogen implanting energy is 20 KeV˜ 3.3 MeV.

6. The method of claim 3, further comprising:
doping the hydrogen-annealed silicon wafer substrate while forming the impurity buried layer.

7. The method of claim 6, wherein the doping concentration is 1×10¹⁹˜ 1×10²²/cm².

8. The method of claim 3, wherein the forming of an impurity buried layer step forms the impurity buried layer using an epitaxial furnace.

9. The method of claim 1, wherein the growing step grows the ingot such that an OSF ring is not formed.

10. The method of claim 9, wherein the growing step includes pulling a seed crystal soaked in fused silicon from a crucible, the pulling speed being more than 0.4 mm/sec.

11. The method of claim 1, wherein the growing step grows the single silicon ingot such that clustering of vacancy defects is restrained.

12. The method of claim 1, wherein the growing step grows the ingot according to the CZ method, wherein a ratio of pulling speed(V) to temperature gradient(G) is more than 0.2 mm²/° C. min.

13. The method of claim 1, wherein the growing step includes doping the ingot at a concentration of 1×10¹⁰˜1×10¹⁸/cm².

14. The method of claim 1, wherein the growing step grows the ingot using a crystal growth furnace having a hot zone of forced cooling type.

15. The method of claim 1, wherein the hydrogen-annealing step comprises the steps of:
washing the silicon wafer substrate; and
removing impurities and a natural oxide film on the surface of the silicon wafer substrate by performing hydrogen-annealing.

16. The method of claim 15, wherein the washing of the silicon wafer substrate is performed using at least one of the vapor phase washing method or the liquid phase washing method.

17. The method of claim 1, wherein the forming step forms the silicon epitaxial layer using SiHCl₃ or SiH₂Cl₂ as a source gas.

18. The method of claim 17, wherein the forming step forms the silicon epitaxial layer at a pressure of 1×10⁻⁴˜1×10⁻⁵ torr and at a temperature of 900˜ 1200°C.

19. The method of claim 18, wherein the forming step forms the silicon epitaxial layer using an epitaxial furnace.

20. A method of manufacturing an epitaxial silicon wafer, comprising:
providing a silicon wafer substrate;
forming an impurity buried layer in the silicon wafer substrate; and
forming a silicon epitaxial layer on the silicon wafer substrate.

21. The method of claim 20, wherein the forming an impurity buried layer forms the impurity buried layer in an upper surface region of the silicon wafer substrate.

22. The method of claim 20, wherein the forming an impurity buried layer forms the impurity buried layer using nitrogen.

23. The method of claim 22, wherein the concentration of nitrogen is 1× 10¹⁰˜1×10¹⁶/cm².

24. The method of claim 20, wherein the providing step provides a silicon wafer substrate without an OSF ring.

25. The method of claim 20, wherein the providing step includes growing a silicon ingot according to the CZ method.

26. The method of claim 24, wherein the growing a silicon ingot step grows the silicon ingot such that a ratio of pulling speed(V) to temperature gradient(G) is more than 0.2 mm²/° C. min.

27. The method of claim 20, further comprising:
hydrogen-annealing the silicon wafer substrate prior to the forming an impurity buried layer step.

28. A method of manufacturing an epitaxial silicon wafer, comprising:
providing a silicon wafer substrate;
forming a contaminant attractor creation layer in the silicon wafer substrate such that, as compared to an absence of the impurity attractor creation layer, a greater number of contaminant attractors are created in the silicon wafer substrate; and
forming a silicon epitaxial layer on the silicon wafer substrate.

29. The method of claim 28, wherein the contaminant attractors remove contaminants from the silicon epitaxial layer during formation of the silicon epitaxial layer.

30. The method of claim 29, wherein the contaminant attractors are oxygen deposits.

31. A method of manufacturing an epitaxial silicon wafer, comprising: providing a silicon wafer substrate;
increasing a number of contaminant attractors in the silicon wafer substrate; and
forming a silicon epitaxial layer on the silicon wafer substrate.

32. The method of claim 31, wherein the contaminant attractors remove contaminants from the silicon epitaxial layer during formation of the silicon epitaxial layer.

33. The method of claim 32, wherein the contaminant attractors are oxygen deposits.
